(19) United States
(12) Patent Application Publication
(10) Pub. No.: US 2017/0249201 A1
(43) Pub. Date: Aug. 31, 2017

(54) CONTROLLER OF SEMICONDUCTOR MEMORY DEVICE AND METHOD OF OPERATING THE SAME

(71) Applicant: SK hynix Inc., Gyeonggi-do (KR)

(72) Inventor: Su Min YI, Gyeonggi-do (KR)

(21) Appl. No.: 15/237,315

(22) Filed: Aug. 15, 2016

(30) Foreign Application Priority Data
Feb. 26, 2016 (KR) 10-2016-0023293

(51) Int. Cl. G06F 11/07; G06F 3/06; G11C 16/26; G11C 16/34; G11C 16/16

(52) U.S. Cl. CPC G06F 11/079; G11C 16/349; G11C 16/16; G11C 16/26; G06F 11/0709; G06F 11/076; G06F 11/0793; G06F 3/0619; G06F 3/0659; G06F 3/0679

(57) ABSTRACT

There are provided an electronic device, and more particularly, to a memory system capable of detecting transmission errors and a method of operating the same. The method of operating the controller configured to control the semiconductor memory device includes generating reception count information by counting a number of bits of a predetermined value of data received from the semiconductor memory device, requesting the semiconductor memory device to transmit transmission count information representing a number of bits of the predetermined value of the data transmitted by the semiconductor memory device and determining whether transmission errors are included in the received data based on the reception count information and the transmission count information.

### CROSS-REFERENCE TO RELATED APPLICATION

The present application claims priority under 35 U.S.C. §119(a) to Korean patent Application No. 10-2016-0023293, filed on Feb. 26, 2016, which is incorporated herein by reference in its entirety.

### BACKGROUND

1. Field

Embodiments of the present invention relate generally to an electronic device and, more particularly, to a memory system and a method of operating the same.

2. Description of the Related Art

Memory systems are widely used as data storage devices of digital devices such as computers, digital cameras, MP3 players, and smart phones. A memory system may include a semiconductor memory device for storing data and a controller for controlling the semiconductor memory device. A digital device is operated by a host of the memory system and the controller transmits commands and data between the host and the semiconductor memory device.

The semiconductor memory device is implemented as an integrated circuit on a chip of a semiconductor material, such as, for example, silicon (SI), germanium (Ge), gallium arsenide (GaAs), and indium phosphide (InP). A semiconductor memory device may be categorized as a volatile or a nonvolatile memory device.

In a volatile memory device, when the power supply to the device is cut off, any stored data therein are lost. A volatile memory device may be, for example, a static random access memory (SRAM), a dynamic RAM (DRAM), or a synchronous DRAM (SDRAM). In a nonvolatile memory device, even when the power supply to the device is cut off, any stored data therein are maintained. A nonvolatile memory device may be, for example, a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), or a ferroelectric RAM (FRAM). A flash memory may be categorized into a NOR flash memory and a NAND flash memory.

### SUMMARY

An embodiment of the present invention relates to a memory system capable of detecting transmission errors and a method of operating the same.

A method of operating a controller configured to control a semiconductor memory device according to an embodiment of the present invention includes generating reception count information by counting a number of bits of a predetermined value of data received from the semiconductor memory device, requesting the semiconductor memory device to transmit transmission count information representing a number of bits of the predetermined value of the data transmitted by the semiconductor memory device and determining whether transmission errors are included in the received data based on the reception count information and the transmission count information.

A method of operating a semiconductor memory device including a plurality of memory cells according to an embodiment of the present invention includes receiving a command, an address, and data from a controller configured to control the semiconductor memory device, generating reception count information by counting a number of bits of a predetermined value of the received data and transmitting the reception count information to the controller in response to a request to transmit the reception count information.

The method of operating the semiconductor memory device further comprising performing an operation corresponding to the received command in response to an operation start command transmitted by the controller.

A method of operating a controller configured to control a semiconductor memory device according to an embodiment of the present invention includes generating transmission count information by counting a number of bits of a predetermined value of data to be transmitted to the semiconductor memory device, transmitting a command, an address, and the data to the semiconductor memory device, requesting the semiconductor memory device to transmit reception count information representing a number of bits of the predetermined value of the data received by the semiconductor memory device and determining whether transmission errors are included in the transmitted data based on the reception count information and the transmission count information.

The method of operating the controller of the embodiment of the present invention wherein the determining includes determining that the transmission errors are not included in the transmitted data when the reception count information coincides with the transmission count information.

The method of operating the controller further comprising retransmitting the command, the address, and the transmitted data to the semiconductor memory device when the transmission errors are included in the transmitted data.

The method of operating the controller further comprising transmitting an operation start command to control the semiconductor memory device to perform the received command when the transmission errors are not included in the transmitted data.

A method of operating a semiconductor memory device including a plurality of memory cells according to an embodiment of the present invention includes generating transmission count information by counting a number of bits of a predetermined value of data to be transmitted to a controller configured to control the semiconductor memory device, transmitting the data to the controller and transmitting the transmission count information to the controller in response to a request to transmit the transmission count information.

The method of operating a semiconductor memory device further comprising retransmitting the data to the controller in response to a retransmission command when it is determined that transmission errors are included in the transmitted data.

A controller configured to control a semiconductor memory device according to an embodiment of the present invention includes a count information generator configured to generate reception count information by counting a number of bits of a predetermined value of data received from the semiconductor memory device and a processor configured to request the semiconductor memory device to transmit transmission count information representing a number of bits of the predetermined value of the data transmitted by the semiconductor memory device, and to determine whether transmission errors are included in the received data based on the reception count information and the transmission count information.

A semiconductor memory device including a plurality of memory cells according to an embodiment of the present invention includes a count information generator configured to generate transmission count information by counting a number of bits of a predetermined value of data to be transmitted to a controller configured to control the semiconductor memory device and a control logic configured to transmit the data to the controller, and to transmit the transmission count information to the controller in response to a request to transmit the transmission count information.

A semiconductor memory device including a plurality of memory cells, the semiconductor memory device comprising, a count information generator configured to generate transmission count information by counting a number of bits of a predetermined value of data to be transmitted to a controller configured to control the semiconductor memory device and a control logic configured to transmit the data to the controller, and to transmit the transmission count information to the controller in response to a request to transmit the transmission count information.

The semiconductor memory device of the embodiment of the present invention, wherein the count information generator comprises, a one bit counter configured to count the number of bits of the predetermined value of the data to be transmitted and a register configured to store an output of the one bit counter.

The semiconductor memory device of the embodiment of the present invention, wherein the control logic retransmits the data to the controller in response to a retransmission command when it is determined that the transmission errors are included in the transmitted data.

A memory system according to an embodiment of the present invention includes a semiconductor memory device configured to transmit data stored in a plurality of memory cells, and to generate transmission count information by counting a number of bits of a predetermined value of the transmitted data and a controller configured to generate reception count information by counting a number of bits of the predetermined value of data received from the semiconductor memory device, and to detect transmission errors of the received data based on the transmission count information and the reception count information.

According to the embodiment of the present invention, there are provided a memory system capable of detecting transmission errors and a method of operating the same.

### BRIEF DESCRIPTION OF THE DRAWINGS

Example embodiments of the present invention will now be described more fully hereinafter with reference to the accompanying drawings; however, the present invention may be embodied in different forms and should not be construed as being limited to the embodiments set forth herein. Rather, these embodiments are provided so that this disclosure will be thorough and complete, and will fully convey the invention to those skilled in the art.

In the drawings, dimensions may be exaggerated for clarity of illustration. It will be further understood that when an element is referred to as being “between” two elements, it can be the only element between the two elements, or one or more intervening elements may also be present. Like reference numerals refer to like elements throughout.

FIG. 1 is a block diagram illustrating a memory system, including a host, a controller and a semiconductor device, according to an embodiment of the invention;

FIG. 2 is a block diagram illustrating a more detailed configuration for the controller of the memory system of FIG. 1, according to an embodiment of the invention;

FIG. 3 is a block diagram illustrating a more detailed configuration for the semiconductor memory device of the memory system of FIG. 1, according to an embodiment of the invention;

FIG. 4 is a view illustrating a structure of a memory cell array employed in the semiconductor memory device of FIG. 3, according to an embodiment of the invention;

FIG. 5 illustrates a structure of a memory cell array employed in the semiconductor memory device of FIG. 3, according to another embodiment of the invention;

FIG. 6 illustrates a structure of a memory cell array employed in the semiconductor memory device of FIG. 3, according to yet another embodiment of the invention;

FIG. 7 is a schematic view illustrating a pin configuration of a semiconductor memory device, according to an embodiment of the invention;

FIG. 8 is a schematic view illustrating a count information generator included in a controller or a semiconductor memory device, according to an embodiment of the invention;

FIG. 9 is a flowchart of an operation of a controller for a memory system, according to an embodiment of the present invention;

FIG. 10 is a flowchart illustrating an operation of a semiconductor memory device, according to an embodiment of the present invention;

FIG. 11 is a flowchart illustrating an operations of a controller, according to another embodiment of the present invention;

FIG. 12 is a flowchart illustrating an operation of a semiconductor memory device, according to another embodiment of the present invention;

FIG. 13 is a block diagram illustrating a memory system including the semiconductor memory device of FIG. 3, according to an embodiment of the invention;

FIG. 14 is a block diagram illustrating an application example of the memory system of FIG. 13, according to an embodiment of the invention; and

FIG. 15 is a block diagram illustrating a computing system including the memory system of FIG. 14, according to an embodiment of the Invention.

### DETAILED DESCRIPTION

The invention will now be described more fully with reference to the accompanying drawings, in which exemplary embodiments of the invention are shown. The invention may, however, be embodied in many different forms and should not be construed as being limited to the exemplary embodiments set forth herein. Rather, these embodiments are provided so that this disclosure will be thorough and complete, and will fully convey the invention to one of ordinary skill in the art to which this invention pertains.

It will be understood that, although the terms first and second, etc., may be used herein to describe various elements, these elements should not be limited by these terms. These terms are only used to distinguish one element from another element. For example, a first element may be named a second element and similarly a second element may be named a first element without departing from the scope of the invention.

It will also be understood that when an element is referred to as being “on” another element, it can be directly on the other element, or intervening elements may also be present. On the other hand, when an element is referred to as being “immediately on” or as “directly contacting” another element, it can be understood that intervening elements do not exist. Other expressions describing a relationship between elements, for example, “between” and “directly between” may be interpreted as described above.

Unless otherwise defined, terms such as “include,” “comprise,” and “have” are inclusive terms representing that certain characteristics, numbers, steps, operations, elements, and parts described in the specification or a combination of the above are present and that one or more other characteristics, numbers, steps, operations, elements, and parts or a combination of the above may also be present.

Unless otherwise defined, all terms (including technical and scientific terms) used herein have the same meaning as commonly understood by one of ordinary skill in the art to which this invention pertains.

In describing the present invention, descriptions of well-known technical information in the art to which the present invention pertains and also of technical information not directly related to an embodiment of the present disclosure which are not needed for the understanding of the present invention will be omitted. This is to allow the embodiments of the present invention to be clearly understood without obscuring the gist of the embodiment of the present disclosure with technical information that is not needed.

Hereinafter, embodiments of the present invention will be described in detail with reference to the accompanying drawings.

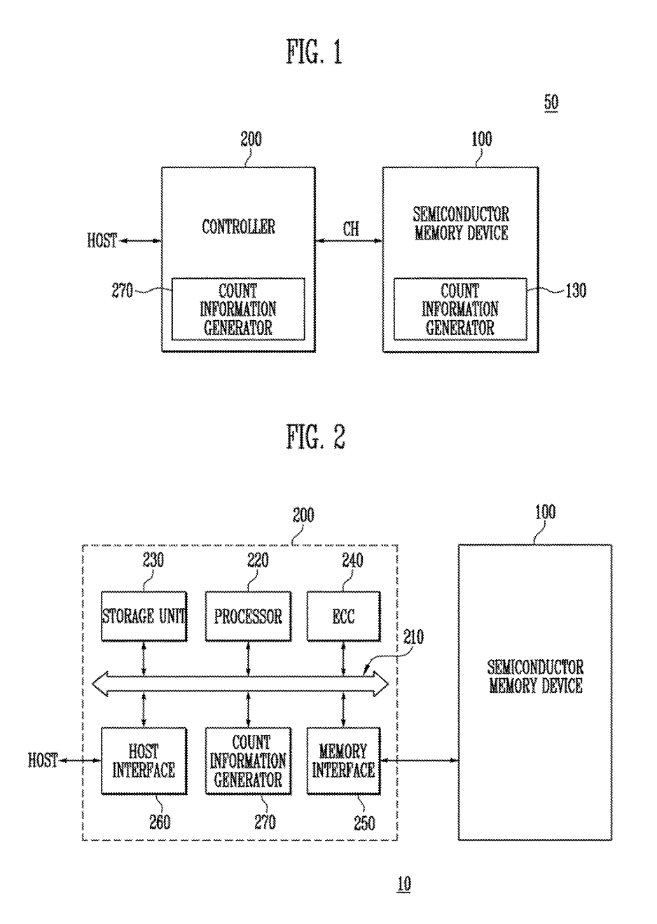

FIG. 1 illustrates a configuration of a memory system 50, according to an embodiment of the invention.

The memory system 50 includes a semiconductor memory device 100 and a controller 200.

The semiconductor memory device 100 may be, for example, a NAND flash memory, a vertical NAND flash memory, a NOR flash memory, a resistive random access memory (RRAM), a phase-change RAM (PRAM), a magneto-resistive RAM (MRAM), a ferroelectric RAM (FRAM), or a spin transfer torque RAM (STT-RAM). In addition, the semiconductor memory device 100, according to an embodiment of the present invention, may have a three-dimensional array structure. The present invention may be applied to a charge trap flash (CTF) in which a charge storage layer is formed of an insulating layer as well as a flash memory device in which a charge storage layer is formed of a conductive floating gate (FG).

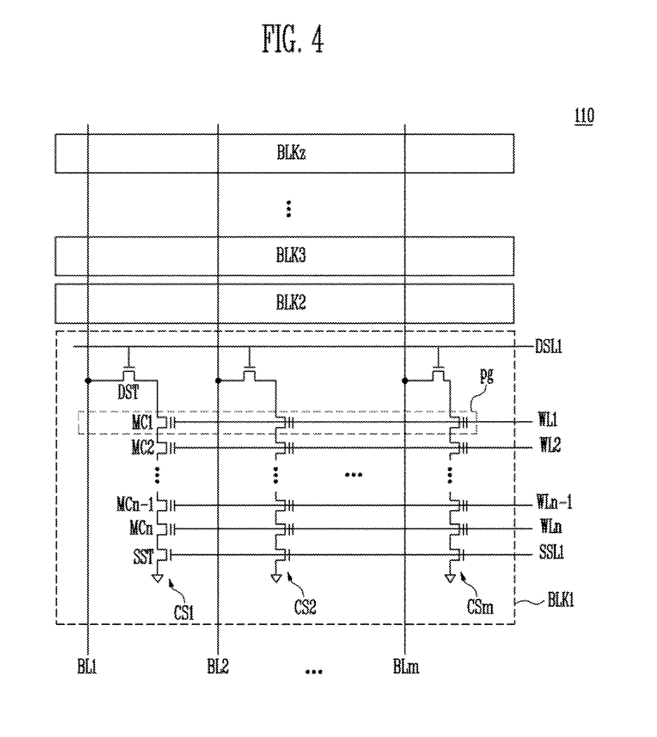

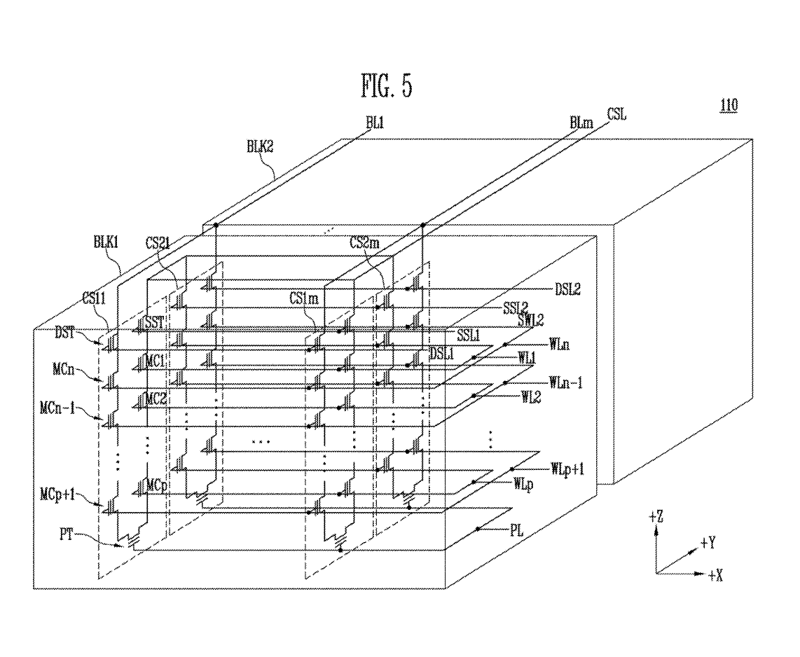

The semiconductor memory device 100 may include a memory cell array 110 for storing data and a peripheral circuit 120 for driving the memory cell array (see FIG. 3). The memory cell array 110 may include a plurality of nonvolatile memory cells (see FIG. 4).

In operation, the semiconductor memory device 100 receives a command and an address from the controller 200 through a channel CH and accesses a region selected by the address in the memory cell array 110 of the semiconductor memory device 100. That is, the semiconductor memory device 100 performs internal operations corresponding to the commands on the region selected by the address received from the controller 200.

For example, the semiconductor memory device 100 may perform a program operation, a read operation, and an erase operation. During a program operation, the semiconductor memory device 100 programs data (writes data) in a region selected by the address received from the controller 200. During a read operation, the semiconductor memory device 100 reads data from the region selected by the address received from the controller 200. During an erase operation, the semiconductor memory device 100 erases data stored in the region selected by the address received from the controller.

The controller 200 controls an entire operation of the semiconductor memory device 100.

For example, the controller 200 may access the semiconductor memory device 100 in response to a request received from a host HOST. The controller 200 transmits a command and an address to the semiconductor memory device 100 in response to the request from the host.

For example, the controller 200 may control the semiconductor memory device 100 to perform a program operation, a read operation, or an erase operation to a memory region corresponding to an address. During a program operation, the controller 200 provides a program command, an address, and data to the semiconductor memory device 100 through the channel CH. During a read operation, the controller 200 provides a read command and an address to the semiconductor memory device 100 through the channel CH. During an erase operation, the controller 200 provides an erase command and an address to the semiconductor memory device 100 through the channel CH.

Error bits may be included in the data received by the controller 200 from the semiconductor memory device 100. The error bits may be generated when the data stored in the semiconductor memory device 100 changes due to physical characteristics of memory cells or may be generated during transmission between the semiconductor memory device 100 and the controller 200 due to the transmission environment.

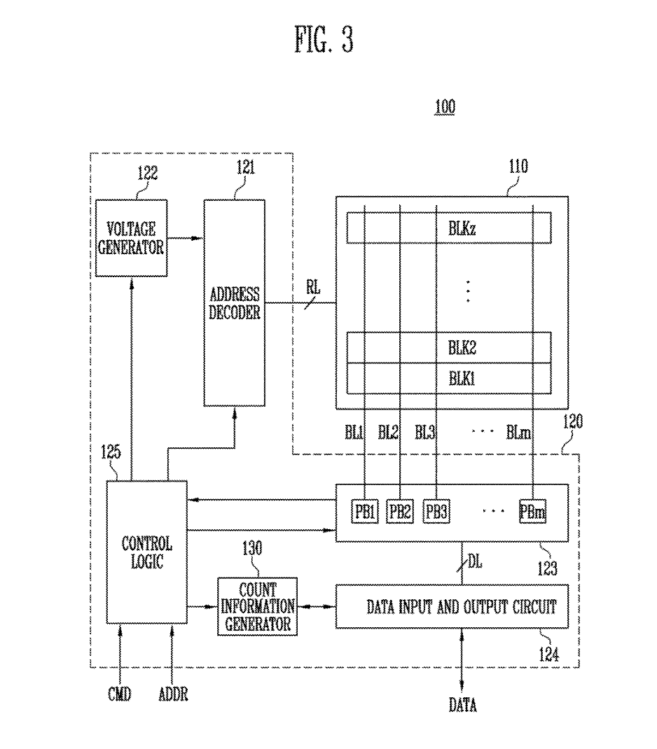

The controller 200 may include an error correcting code (ECC) 240 (see FIG. 2) for correcting the error bits in the transmitted data. As the transmission speed between the controller 200 and the semiconductor memory device 100 increases and an amount of transmitted and received data increases, it is necessary to determine whether the generated error bits are errors due to the physical characteristics of the memory cells (“normal errors”) or transmission errors caused by the transmission.

Error bits may occur in the data transmitted between the controller 200 and the semiconductor memory device 100 due to the transmission environment (“transmission errors”). According to an embodiment, the controller 200 may detect transmission errors in the transmitted data, and retransmit the data having transmission errors detected, hereinafter referred to as transmission-error-detected data, thereby preventing programming the data including error bits due to the transmission environment.

In the memory system 50 according to an embodiment of the present invention, the controller 200 may determine whether there are transmission errors in the data transmitted between the semiconductor memory device 100 and the controller 200. According to the embodiment of FIG. 1, both the semiconductor memory device 100 and the controller 200 include count information generators 130 and 270, respectively, for counting the number of bits of “0” or “1” included in the transmitted and received data for detecting transmission errors.

FIG. 2 is a block diagram illustrating a more detailed configuration for the controller 200 of FIG. 1, according to an embodiment of the invention.

Referring to the embodiment of FIG. 2, the controller 200 is connected to the host and the semiconductor memory device 100. In operation, in response to a request from the host, the controller 200 accesses the semiconductor memory device 100. For example, the controller 200 may control a read operation, program and an erase operation of the semiconductor memory device 100. The controller 200 provides an interface between the semiconductor memory device 100 and the host. The controller 200 may drive firmware for controlling the semiconductor memory device 100. In an embodiment, the semiconductor memory device 200 may include a flash memory device.

According to the illustrated embodiment of FIG. 2, the controller 200 includes an internal bus 210, a processor 220, a buffer memory 230, an error correcting circuit block 240, a memory interface 250, a host interface 260, and a count information generator 270.

The internal bus 210 provides communication channels among the various elements of the controller 200. For example, the internal bus 210 may be a common channel for transmitting the commands and the data. According to an embodiment, the Internal bus 210 may include a command channel for transmitting commands and a data channel for transmitting data.

The processor 220 controls an entire operation of the controller 200. For example, the processor 220 may execute software and/or firmware driven by the controller 200. The processor 220 may operate firmware, such as, for example, a flash translation layer (FTL). The FTL may provide various units for controlling the semiconductor memory device 100. The FTL may include one or more tables with information on a mapping relationship between a logical block address received form the host and a physical block address corresponding to a physical memory region of the semiconductor memory device. The FTL may maintain the tabled information. According to an embodiment, the FTL may include a wear levelling unit for evenly spreading the number of programs and erases between the memory blocks of the semiconductor memory device 100. The FTL may minimize the number of erases of the semiconductor memory device 100. For example, the FTL may include control units, such as, a merge, a garbage collection, and a copy back unit.

In operation, when a request is received from the host through the host interface 260, the processor 220 may generate a physical block address corresponding to the corresponding request.

The processor 220 may convert the logical block address included in the request from the host into the physical block address. When the request from the host is a program request, program-requested data may be received from the host. The processor 220 may store the physical block address, the program-requested data, and a program command corresponding to a program request in the storage unit 230. The program command, the physical block address, and the program-requested data that are stored in the storage unit 230 are transmitted to the semiconductor memory device 100 through the memory interface 250.

When a request from the host is a read request, the processor 220 may store the physical block address and the read command corresponding to the read request in the storage unit 230. The read command and the physical block address that are stored in the storage unit 230 are transmitted to the semiconductor memory device 100 through the memory interface 250. The semiconductor memory device 100 accesses memory cells corresponding to the physical block address received from the controller 200, reads data stored in the corresponding memory cells, and transmits the read-requested data to the controller 200.

According to the illustrated embodiment of FIG. 3, a command, for example, a program command or a read command is indicated as “CMD,” a physical block address is indicated as “ADDR,” and program-requested data are indicated as “DATA.”

The storage unit 230 may be used as a working memory of the processor 220 or a buffer memory between the semiconductor memory device 100 and the host. According to an embodiment, the storage unit 230 may be used as a cache memory between the semiconductor memory device 100 and the host or a buffer for temporarily storing data input from the semiconductor memory device 100. For example, the storage unit 230 may include at least one of various random access memories (RAMs), such as, a static random access memory (RAM) (SRAM), a dynamic RAM (DRAM), a synchronous DRAM (SDRAM), a phase-change RAM (PRAM), a magnetic RAM (MRAM), a resistive RAM (RRAM), a ferroelectric RAM (FRAM), and a NOR flash memory.

The ECC 240 detects errors of the data read from the semiconductor memory device 100 and corrects the detected errors.

The memory interface 250 includes a protocol for communicating with the semiconductor memory device 100. For example, in an embodiment, the memory interface 250 may include at least one of a flash interface, such as, a NAND interface and a NOR interface.

The host interface 260 includes a protocol for exchanging data between the host HOST and the controller 200. For example, the controller 200 may communicate with the host HOST (or some other external device) through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol.

The count information generator 270 generates count information on the data transmitted and received between the controller 200 and the semiconductor memory device 100. During a program operation, the count information generator 270 generates the count information on the data transmitted from the controller 200 to the semiconductor memory device 100. During a read operation, the count information generator 270 generates the count information on the data received from the semiconductor memory device 100. The count information generator 270 generates transmission count information obtained by counting the number of bits of “0” or “1” included in the data transmitted to the semiconductor memory device 100. The count information generator 270 generates reception count information obtained by counting the number of bits of “0” or “1” included in the data received from the semiconductor memory device 100. In an embodiment, the generated transmission count information or reception count information may be stored in a register (not shown) included in the count information generator. According to an embodiment, the transmission count information or the reception count information may be stored in a partial region of the storage unit 230.

When data received form the host is transmitted to the semiconductor memory device 100, the controller 200 may request the semiconductor memory device 100 to transmit the reception count information generated by the semiconductor memory device 100. The controller 200 then compares the reception count information transmitted from the semiconductor memory device 100 and the transmission count information generated by the count information generator 270 and may thus detect the transmission errors.

FIG. 3 is a block diagram illustrating a detailed configuration of the semiconductor memory device of FIG. 1 including the memory cell array 110 and the peripheral circuit 120, according to an embodiment of the invention.

FIG. 4 illustrates a structure of the memory cell array of FIG. 3, according to an embodiment of the invention.

Referring to FIG. 3, the memory cell array 110 includes a plurality of memory blocks BBLK1 to BLKz. The plurality of memory blocks BBLK1 to BLKz are connected to an address decoder 121 through row lines RL and are connected to a read and write circuit 123 through bit lines BL1 to BLm. Each of the plurality of memory blocks BBLK1 to BLKz includes a plurality of memory cells. According to an embodiment, the plurality of memory cells are nonvolatile memory cells such as, for example, flash memory cells.

The plurality of memory cells included in the memory cell array 100 may be divided into a system block and a user block in accordance with the purpose for which they are used.

Referring to FIG. 4, the first to zth memory blocks BLK1 to BLKz are commonly connected to the first to mth bit lines BL1 to BLm. In FIG. 4, for the sake of convenience, among the plurality of memory blocks BBLK1 to BLKz, only elements included in the first memory block BLK1 are illustrated and elements included in each of the remaining memory blocks BLK2 to BLKz are omitted. However, we note that each of the remaining memory blocks BLK2 to BLKz may be configured like the first memory block BLK1.

According to the embodiment of FIG. 4, the memory block BLK1 includes a plurality of cell strings CS1 to CSm. The first to mth cell strings CS1 to CSm are respectively connected to the first to mth bit lines BL1 to BLm.

Each of the first to mth cell strings CS1 to CSm includes a drain select transistor DST, a plurality of serially connected memory cells MC1 to MCn, and a source select transistor SST, all serially connected. Each of the drain select transistors DST is connected to a common drain select line DSL1. The first to nth memory cells MC1 to MCn are respectively connected to first to nth word lines WL1 to WLn. Each of the source select transistors SST is connected to a common source select line SSL1. A drain of each drain select transistor DST is connected to a corresponding bit line. Drain select transistors of the first to mth cell strings CS1 to CSm are connected to the first to mth bit lines BL1 to BLm, respectively. A source of the source select transistor SST is connected to a common source line CSL. According to an embodiment, the common source line CSL may be commonly connected to the first to zth memory blocks BLK1 to BLKz.

The drain select line DSL1, the first to nth word lines WL1 to WLn, and the source select line SSL1 are included in the row lines RL of FIG. 3. The drain select line DSL1, the first to nth word lines WL1 to WLn, and the source select line SSL1 are controlled by the address decoder 121. The common source line CSL is controlled by a control logic 125. The first to mth bit lines BL1 to BLm are controlled by the read and write circuit 123.

According to the embodiment of FIG. 3, the peripheral circuit 120 includes the address decoder 121, a voltage generator 122, the read and write circuit 123, a data input and output circuit 124, the control logic 125, and the count information generator 130.

The address decoder 121 is connected to the memory cell array 110 through the row lines RL. The address decoder 121 operates in response to control of the control logic 125. The address decoder 121 receives the address ADDR through the control logic 125.

According to an embodiment, the program and read operations of the semiconductor memory device 100 are performed in units of pages.

For example, during a program or a read operation, the address ADDR received by the control logic 125 may include a block address and a row address. The address decoder 121 may then decode the block address in the received address ADDR. The address decoder 121 then may select one of the memory blocks BLK1 to BLKz in accordance with the decoded block address.

The address decoder 121 also decodes the row address in the received address ADDR. The address decoder 121 applies voltages received from the voltage generator 122 to the row lines RL in accordance with the decoded row address and selects a word line of the selected memory block.

According to an embodiment, the erase operations of the semiconductor memory device 100 are performed in units of memory blocks.

For example, during an erase operation, the address ADDR may include the block address. The address decoder 121 may then decode the block address and select one memory block in accordance with the decoded block address for performing the erase operation.

According to an embodiment, the address decoder 121 may include a block decoder, a word line decoder, and an address buffer.

The voltage generator 122 may generate a plurality of voltages by using an external power source voltage supplied to the semiconductor memory device 100. The voltage generator 122 operates in response to the control of the control logic 125.

According to an embodiment, the voltage generator 122 may regulate the external power source voltage and generate an internal power source voltage. The internal power source voltage generated by the voltage generator 122 is used as an operating voltage of the semiconductor memory device 100.

According to an embodiment, the voltage generator 122 may generate the plurality of voltages by using the external power source voltage or the internal power source voltage. For example, the voltage generator 122 may include a plurality of pumping capacitors that receive the internal power source voltage and generate the plurality of voltages by selectively activating the plurality of pumping capacitors in response to the control of the control logic 125. The plurality of generated voltages may be applied to the selected word line by the address decoder 121.

For example, during a program operation, the voltage generator 122 generates a high voltage program pulse and a pass pulse lower than the program pulse. During a read operation, the voltage generator 122 generates a read voltage and a pass voltage higher than the read voltage. During an erase operation, the voltage generator 122 generates an erase voltage.

The read and write circuit 123 may include first to mth page buffers PB1 to PBm as illustrated in the embodiment of FIG. 3. The first to mth page buffers PB1 to PBm are connected to the memory cell array 110 through the first to mth bit lines BL1 to BLm. The first to mth page buffers PB1 to PBm operate in response to the control of the control logic 125.

The first to mth page buffers PB1 to PBm communicate data with the data input and output circuit 124. During the program operation, the first to mth page buffers PB1 to PBm receive data DATA to be stored through the data input and output circuit 124 and data lines DL.

During a program operation, the first to mth page buffers PB1 to PBm transmit the data DATA received through the data input and output circuit 124 to selected memory cells through the bit lines BL1 to BLm when a program pulse is applied to a selected word line. The memory cells of a selected page are programmed in accordance with the received data DATA. A memory cell connected to a bit line to which a program allow voltage (for example, a ground voltage) is applied has an increased threshold voltage. A threshold voltage of a memory cell connected to a bit line to which a program prevent voltage (for example, a power source voltage) is applied is maintained. During a program verify operation, the first to mth page buffers PB1 to PBm read page data from the selected memory cells through the bit lines BL1 to BLm.

During a read operation, the read and write circuit 123 reads the data DATA from the memory cells of the selected page through the bit lines BL and outputs the read-requested data DATA to the input and output circuit 124.

During the erase operation, the read and write circuit 123 may make the bit lines BL float.

According to an embodiment, the read and write circuit 123 may include a column select circuit.

The data input and output circuit 124 is connected to first to mth page buffers PB1 to PBm through the data lines DL. The data input and output circuit 124 operates in response to the control of the control logic 125. During a program operation, the data input and output circuit 124 receives the data DATA to be stored from the controller 200. During the read operation, the data input and output circuit 124 receives the data DATA read from the read and write circuit 123 and outputs the received data DATA to the controller 200.

As described with reference to FIGS. 1 and 2, the count information generator 130 generates the transmission count information or the reception count information of the input and output data of the semiconductor memory device 100.

When the data (e.g., read-requested data) to be transmitted to the controller 200 is transmitted to the data input and output circuit 124, the count information generator 130 generates the transmission count information of the read-requested data. The count information generator 130 generates the transmission count information by counting the number of bits of “0” or “1” included in the read-requested data.

When the data (e.g., program-requested data) received from the controller 200 is input to the data input and output circuit 124, the count information generator 130 generates the reception count information of the program-requested data. The count information generator 130 generates the reception count information obtained by counting the number of bits of “O” or “1” included in the program-requested data.

According to an embodiment, the count information generator 130 may be implemented in the data input and output circuit 124.

The control logic 125 is connected to the address decoder 121, the voltage generator 122, the read and write circuit 123, the data input and output circuit 124, and the count information generator 130. The control logic 125 may control an entire operation of the semiconductor memory device 100. For example, as illustrated in FIG. 3, the control logic 125 receives the command CMD and the address ADDR from the controller 200. The control logic 125 then may control the address decoder 121, the voltage generator 122, the read and write circuit 123, the data input and output circuit 124, and the count information generator 130 in response to the command CMD.

The control logic 125 may receive a request to transmit the count information from the controller 200. When the control logic 125 receives the request to transmit the count information from the controller 200, the control logic 125 may transmit the transmission count information or the reception count information to the controller 200.

According to an embodiment, during a program operation, the control logic 125 may receive a program command, an address and program-requested data. When the program-requested data is received, the count information generator 130 generates the reception count information of the program-requested data. The count information generator 130 generates the reception count information by counting the number of bits of “0” or “1” included in the program-requested data. The control logic 125 may delay performing the program operation until an operation start command is received from the controller 200.

When the control logic 125 receives the request to transmit the count information from the controller 200, the control logic 125 may transmit the generated reception count information to the controller 200.

Then, when the control logic 125 receives the operation start command from the controller 200, the control logic 125 may start the held back program operation.

According to an embodiment, during a read operation, the control logic 125 receives the read command and address. The control logic 125 controls the address decoder 121, the voltage generator 122, the read and write circuit 123, and the data input and output circuit 124 and reads read-requested data stored in memory cells corresponding to a selected address. The count information generator 130 generates the transmission count information of the read-requested data to be transmitted. The count information generator 130 generates the transmission count information by counting the number of bits of “O” or “1” included in the read-requested data to be transmitted.

When the control logic 125 receives the request to transmit the count information from the controller 200, the control logic 125 may transmit the generated transmission count information to the controller 200.

According to an embodiment of the present invention, the semiconductor memory device 100 generates the reception count information or the transmission count information of the input and output data. The semiconductor memory device 100 transmits the reception count information or the transmission count information to the controller 200 in response to the request of the controller 200.

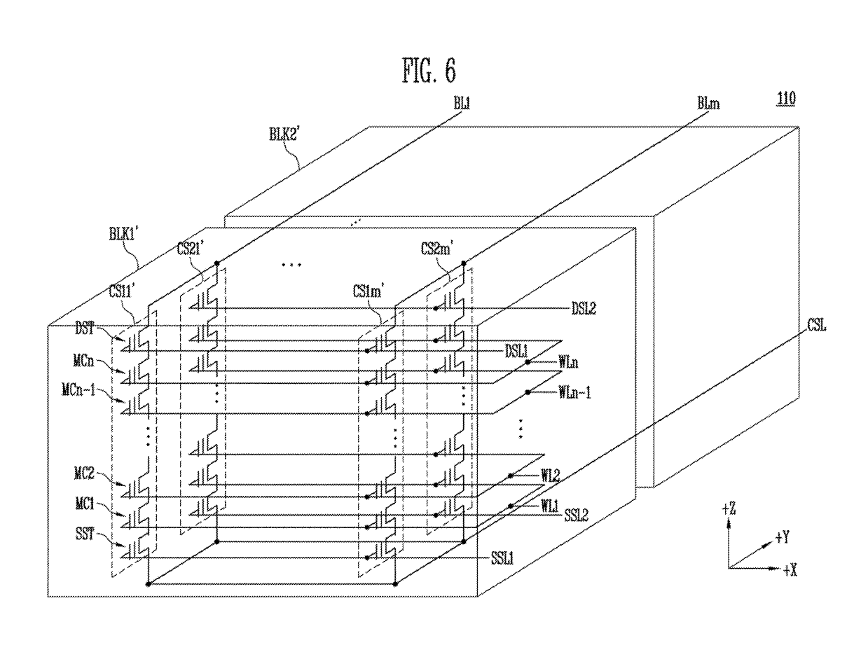

FIG. 5 illustrates another embodiment of the memory cell array of FIG. 3.

Referring to FIG. 5, the memory cell array 110 includes the plurality of memory blocks BLK1 to BLKz. In FIG. 5, for convenience sake, an internal configuration of the first memory block BLK1 is illustrated and internal configurations of the remaining memory blocks BLK2 to BLKz are omitted. The second to zth memory blocks BLK2 to BLKz are configured like the first memory block BLK1.

Referring to FIG. 5, the first memory block BLK1 includes a plurality of cell strings CS11 to CS1m and CS21 to CS2m. According to an embodiment, each of the plurality of cell strings CS11 to CS1m and CS21 to CS2m may be U-shaped. In the first memory block BLK1, m cell strings are arranged in a row direction (that is, in a +X direction). In FIG. 5, it is illustrated that two cell strings are arranged in a column direction (that is, in a +Y direction). However, three or more cell strings may be arranged in the column direction.

Each of the plurality of cell strings CS11 to CS1m and CS21 to CS2m includes at least one source select transistor SST, first to nth memory cells MC1 to MCn, a pipe transistor PT, and at least one drain select transistor DST, all connected in series.

The select transistors SST and DST and the memory cells MC1 to MCn may have similar structures. According to an embodiment, each of the select transistors SST and DST and the memory cells MC1 to MCn may include a channel layer, a tunneling insulating layer, a charge storage layer, and a blocking insulating layer. According to an embodiment, a pillar for providing the channel layer may be provided in each cell string. According to an embodiment, the pillar for providing at least one of the channel layer, the tunneling insulating layer, the charge storage layer, and the blocking insulating layer may be provided in each cell string.

The source select transistor SST of each cell string is connected between the common source line CSL and the memory cells MC1 to MCp.

According to an embodiment, source select transistors of cell strings arranged in the same row are connected to a source select line that extends in the row direction and source select transistors of cell strings arranged in different rows are connected to different source select lines. In FIG. 5, the source select transistors of the cell strings CS11 to CS1m in a first row are connected to the first source select line SSL1. The source select transistors of the cell strings CS21 to CS2m in a second row are connected to a second source select line SSL2.

According to another embodiment, the source select transistors of the cell strings CS11 to CS1m and CS21 to CS2m may be commonly connected to one source select line.

The first to nth memory cells MC1 to MCn of each cell string are connected between the source select transistor SST and the drain select transistor DST.

The first to nth memory cells MC1 to MCn are divided into the first to pth memory cells MC1 to MCp and (p+1)th to nth memory cells MCp+1 to MCn. The first to pth memory cells MC1 to MCp are sequentially arranged in a direction opposite to a +Z direction and are serially connected between the source select transistor SST and the pipe transistor PT. The (p+1)th to nth memory cells MCp+1 to MCn are sequentially arranged in the +Z direction and are serially connected between the pipe transistor PT and the drain select transistor DST. The first to pth memory cells MC1 to MCp and the (p+1)th to nth memory cells MCp+1 to MCn are connected through the pipe transistor PT. Gates of the first to nth memory cells MC1 to MCn of each cell string are respectively connected to the first to nth word lines WL1 to WLn.

According to an embodiment, at least one of the first to nth memory cells MC1 to MCn may be used as a dummy memory cell. When the dummy memory cell is provided, a voltage or a current of a corresponding cell string may be stably controlled. Therefore, reliability of data stored in the memory block BLK1 improves.

A gate of the pipe transistor PT of each cell string is connected to a pipe line PL.

The drain select transistor DST of each cell string is connected between a corresponding bit line and the memory cells MC(p+1) to MCn. Cell strings arranged in the row direction are connected to a drain select line that extends in the row direction. Drain select transistors of the cell strings CS11 to CS1m of the first row are connected to the first drain select line DSL1. Drain select transistors of the cell strings CS21 to CS2m of the second row are connected to the second drain select line DSL2.

Cell strings arranged in the column direction are connected to a bit line that extends in the column direction. In FIG. 5, the cell strings CS11 and CS21 in a first column are connected to the first bit line BL1. The cell strings CS1m and CS2m in an mth column are connected to the mth bit line BLm.

Memory cells connected to the same word line in the cell strings arranged in the row direction form one page. For example, memory cells connected to the first word line WL1 among the cell strings CS11 to CS1m in the first row form one page. Memory cells connected to the first word line WL1 among the cell strings CS21 to CS2m in the second row form one page. One of the drain select lines DSL1 and DSL2 is selected so that cell strings arranged in one row direction are selected. One of the word lines WL1 to WLn is selected so that one page is selected among the selected cell strings.

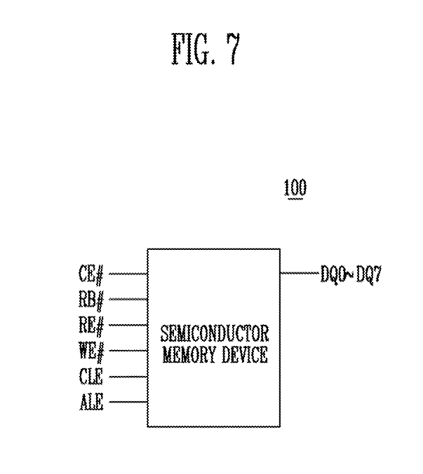

FIG. 6 illustrates another embodiment of the memory cell array of FIG. 3.

Referring to FIG. 6, the memory cell array 110 includes a plurality of memory blocks BLK1′ to BLKz′. In FIG. 6, for convenience sake, an internal configuration of the first memory block BLK1′ is illustrated and internal configurations of the remaining memory blocks BLK2′ to BLKz′ are omitted. The second to zth memory blocks BLK2′ to BLKz′ are configured like the first memory block BLK1′.

The first memory block BLK1′ includes a plurality of cell strings CS11′ to CS1m′ and CS21′ to CS2m. The plurality of cell strings CS11′ to CS1m′ and CS21′ to CS2m′ extend in the +Z direction. In the first memory block BLK1′, m cell strings are arranged in the +X direction. In FIG. 5, it is illustrated that two cell strings are arranged in the +Y direction. However, no less than three cell strings may be arranged in the column direction.

Each of the plurality of cell strings CS11′ to CS1m′ and CS21′ to CS2m′ Includes at least one source select transistor SST, first to nth memory cells MC1 to MCn, and at least one drain select transistor DST.

The source select transistor SST of each cell string is connected between the common source line CSL and the memory cells MC1 to MCn. Source select transistors of cell strings arranged in the same row are connected to the same source select line. The source select transistors of the cell strings CS11′ to CS1m′ in a first row are connected to the first source select line SSL1. The source select transistors of the cell strings CS21′ to CS2m′ in a second row are connected to a second source select line SSL2. According to another embodiment, the source select transistors of the cell strings CS11′ to CS1m′ and CS21′ to CS2m′ may be commonly connected to one source select line.

The first to nth memory cells MC1 to MCn of each cell string are serially connected between the source select transistor SST and the drain select transistor DST. Gates of the first to nth memory cells MC1 to MCn are respectively connected to the first to nth word lines WL1 to WLn.

According to an embodiment, at least one of the first to nth memory cells MC1 to MCn may be used as a dummy memory cell. When the dummy memory cell is provided, a voltage or a current of a corresponding cell string may be stably controlled. Therefore, reliability of data stored in the memory block BLK1′ improves.

The drain select transistor DST of each cell string is connected between a corresponding bit line and the memory cells MC1 to MCn. Drain select transistors of the cell strings arranged in the row direction are connected to a drain select line that extends in the row direction. Drain select transistors of the cell strings CS11′ to CS1m′ of the first row are connected to the first drain select line DSL1. Drain select transistors of the cell strings CS21′ to CS2m′ of the second row are connected to the second drain select line DSL2.

As a result, the memory block BLK1′ of FIG. 6 has an equivalent circuit similar to the memory block BLK1 of FIG. 5 excluding that the pipe transistor PT is excluded from each cell string.

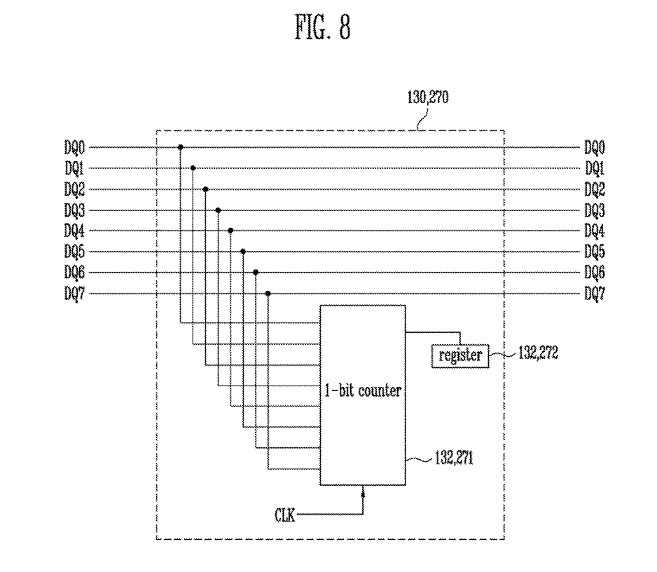

FIG. 7 is a view illustrating a pin configuration of the semiconductor memory device 100.

Referring to FIG. 7, the semiconductor memory device 100 communicates with the controller 200 through a plurality of lines.

The semiconductor memory device 100 communicates with the controller 200 through a chip enable CE# line, a command latch enable CLE line, an address latch enable ALE line, a write enable WE# line, a read enable RE# line, a ready busy RB# line, and data input and output DQ0 to DQ7 lines.

The chip enable CE# line signal represents that the corresponding semiconductor memory device 100 may operate. The chip enable CE# line signal may be selectively applied to storage devices connected to the same channel. The chip enable CE# line signal represents that all operations in the corresponding chip may be performed while being transited to a low level. When the chip enable CE# line signal is at a high level, the corresponding chip may be in a standby state.

The ready busy RB# line signal is transited to a low level while an operation is performed in a chip and prevents the chip from transmitting and receiving another signal to and from the outside. When the ready busy RB# line signal is at a high level, the ready busy RB# line signal represents that the chip is in a ready state.

The command latch enable signal CLE is at a high level while the command CMD is transmitted to a storage device. The address latch enable signal ALE is at a high level while the address ADDR is transmitted to a storage device.

The command CMD and the address ADD are input to selected storage devices when the write enable signal WE# is transited from a high level to a low level.

The write enable signal WE# is toggled when the command and the address are loaded in the storage devices and the read enable signal RE# Is toggled when data is loaded in the controller 200.

The data input and output DQ0 to DQ7 lines input commands, addresses, and data to the semiconductor memory device 100 or output data from the semiconductor memory device 100 to the controller 200. Since eight-bit data is provided, the number of data input and output DQ0 to DQ7 lines is eight. The number of data input and output lines is not limited to eight and may be 16 or 32 according to various embodiments.

FIG. 8 is a view illustrating the count information generator 130 or 270 included in the controller 200 or the semiconductor memory device 100.

The count information generator 270 and the count information generator 130 of FIGS. 1 to 3 may have the same configuration.

As described above, the count information generator 270 of FIG. 2 is included in the controller 200 and the count information generator 130 of FIG. 3 is included in the semiconductor memory device 100. The count information generators 130 and 270 of the semiconductor memory device 100 and the controller 200 generate count information of the data input or output to the semiconductor memory device 100 and the controller 200, respectively. The count information generator 130 of the semiconductor memory device 100 generates the transmission count information of the data to be transmitted to the controller 200 and generates the reception count information of the reception data received from the controller 200. The controller 200 generates the transmission count information of the data to be transmitted to the semiconductor memory device 100. The controller 200 also generates the reception count information of the reception data received from the semiconductor memory device 100.

Referring to FIG. 8, the count information generators 130 and 270 may respectively include one-bit counters 131 and 271 and registers 132 and 272. According to an embodiment, the semiconductor memory device 100 and the controller 200 may transmit and receive the eight-bit data in each cycle. The count information generators 130 and 270 receive the data of the eight input and output lines and may generate the count information in units of cycles.

The one-bit counters 131 and 271 may generate the count information by counting the number of bits of “0” or “1” included in the plurality of data input and output lines. The one-bit counters 131 and 271 obtain the number of bits of “0” (or “1”) among the data input to the data input and output lines DQ0 to DQ7 every cycle and may store the obtained number in the registers 132 and 272.

The stored count information may correspond to one of the transmission count information and the reception count information in accordance with an input and output direction of the data.

When the data (e.g., the program-requested data) is input from the controller 200 to the semiconductor memory device 100 (hereinafter, referred to as DATA-IN), the count information generator 270 of the controller 200 generates the transmission count information of the data DATA-IN and the count information generator 130 of the semiconductor memory device 100 generates the reception count information of the data DATA-IN.

When the data (e.g., the read-requested data) is output from the semiconductor memory device 100 to the controller 200 (hereinafter, referred to as DATA-OUT), the count information generator 130 of the semiconductor memory device 100 generates the transmission count information of the data DATA-OUT and the count information generator 270 of the controller 200 generates the reception count information of the data DATA-OUT.

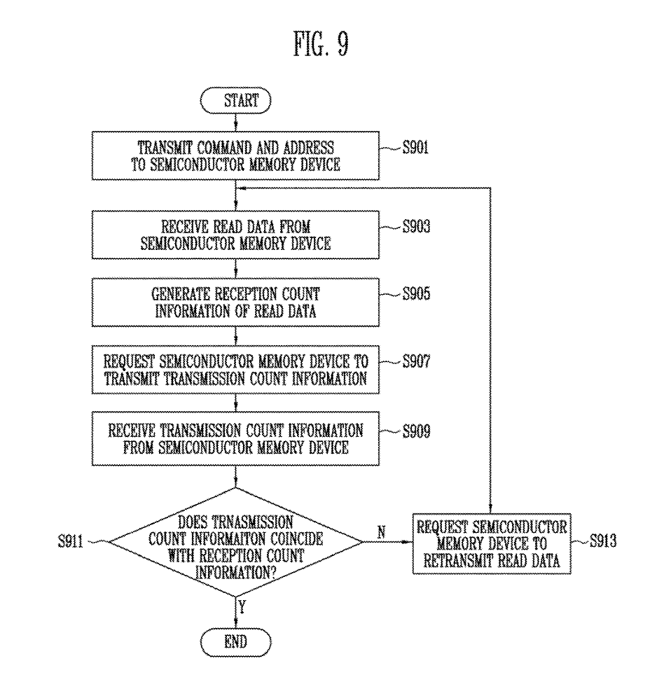

Hereinafter, operations of the controller 200 and the semiconductor memory device 100 in accordance with a case of DATA-OUT and a case of DATA-IN will be described in more detail with reference to FIGS. 9 to 12.

FIG. 9 is a flowchart illustrating operations of the controller 200, according to an embodiment of the present invention.

In the embodiment of FIG. 9, the operation of the controller 200 in a case of DATA-OUT is illustrated.

In step S901, the controller 200 transmits the command and the address to the semiconductor memory device 100. According to an embodiment, the command transmitted by the controller 200 may be the read command corresponding to the read operation and the address may include the physical block address for performing the read operation. Here, the physical block address may represent one of the plurality of pages of the memory cell array 110.

In step S903, the controller 200 receives the data DATA-OUT read from the semiconductor memory device 100.

In step S905, the controller 200 generates the reception count information of the data DATA-OUT. The count information generator 270 described with reference to FIG. 8 counts the number of bits of “0” or “1” included in the received data DATA-OUT, generates the reception count information, and may store the generated reception count information in the register 272.

When the semiconductor memory device 100 transmits the data DATA-OUT to the controller 200 in the step S903, the semiconductor memory device 100 generates the transmission count information of the data DATA-OUT by counting the number of bits of “0” or “1” included in the transmitted data DATA-OUT and stores the generated transmission count information.

In step S907, the controller 200 requests the semiconductor memory device 100 to transmit the transmission count information of the data DATA-OUT.

In step S909, the controller 200 receives the transmission count information of the data DATA-OUT from the semiconductor memory device 100.

In step S911, the controller 200 may determine whether the transmission count information of the data DATA-OUT received from the semiconductor memory device 100 coincides with the reception count information of the data DATA-OUT generated by the controller 200. When the transmission count information generated by the semiconductor memory device 100 coincides with the reception count information generated by the controller 200, it is determined that the transmission errors do not occur. Therefore, when the transmission count information coincides with the reception count information, the process is terminated. According to various embodiments, although not shown in FIG. 9, when the transmission errors do not occur, the controller 200 may perform an error correcting operation on the data DATA-OUT.

When the step S911 that the transmission count information does not coincide with the reception count information generated by the controller 200, it is determined that the transmission errors occur. At this time, the process proceeds to step S913.

In the step S913, the controller 200 requests the semiconductor memory device to retransmit the data DATA-OUT. According to an embodiment, the controller 200 may transmit a command requesting the semiconductor memory device 100 to retransmit the data DATA-OUT to the semiconductor memory device 100.

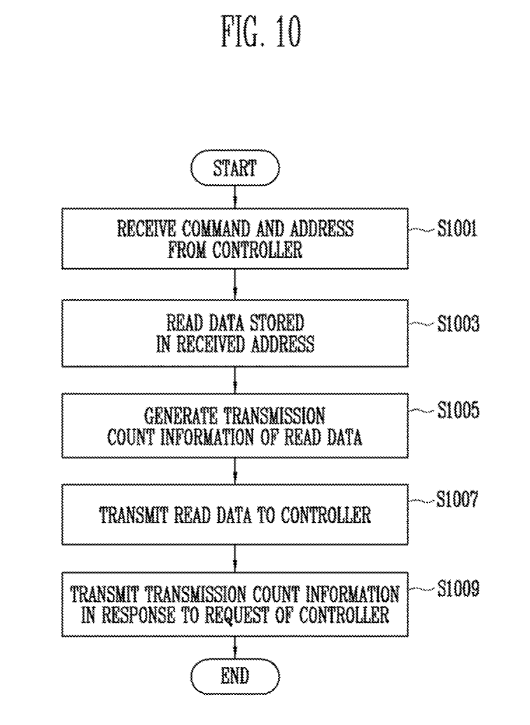

FIG. 10 is a flowchart illustrating an operation of the semiconductor memory device 100, according to an embodiment of the present invention.

In the embodiment of FIG. 10, the operation of the semiconductor memory device in the case of DATA-OUT is illustrated.

In step S1001, the semiconductor memory device 100 may receive the command and the address from the controller 200. According to an embodiment, the command received by the semiconductor memory device 100 may be the read command and the address may include the physical block address for performing the read operation. Here, the physical block address may represent one of the plurality of pages of the memory cell array.

In step S1003, the semiconductor memory device 100 may read the data DATA-OUT stored in a page corresponding to the address received in the step S1001.

In step S1005, the semiconductor memory device 100 may generate the transmission count information of the data DATA-OUT before transmitting the data DATA-OUT to the controller 200. Specifically, the count information generator 130 described with reference to FIG. 8 counts the number of bits of “0” or “1” included in the data DATA-OUT, generates the transmission count information of the data DATA-OUT, and stores the generated transmission count information in the register 132.

In step S1007, the semiconductor memory device 100 transmits the data DATA-OUT to the controller 200.

In step S1009, the semiconductor memory device 100 transmits the transmission count information of the data DATA-OUT generated in the step S1005 to the controller 200 in response to the request of the controller 200. Specifically, when the command requesting the semiconductor memory device 100 to transmit the transmission count information is received from the controller 200, the semiconductor memory device 100 may transmit the transmission count information of the data DATA-OUT to the controller 200 in response to the received command.

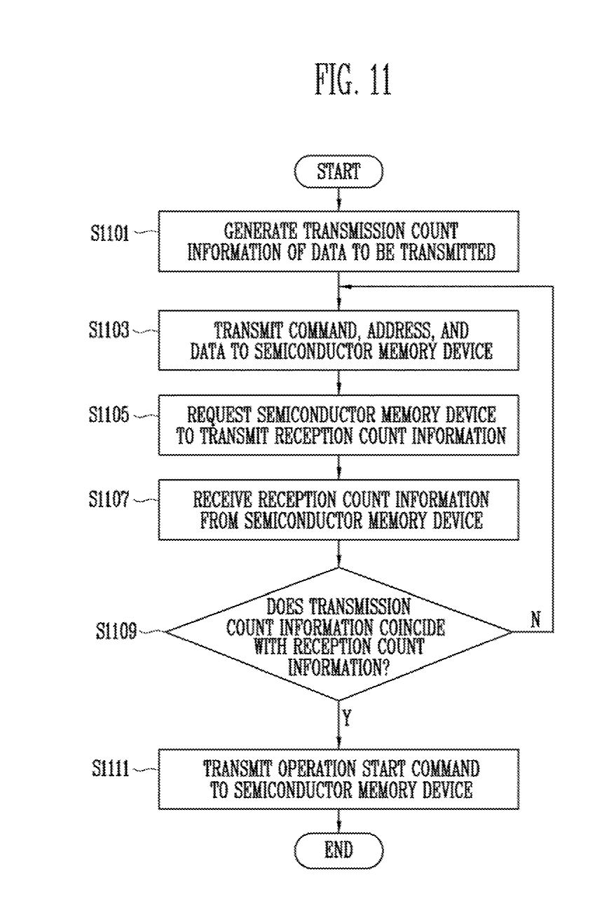

FIG. 11 is a flowchart illustrating an operation of the controller 200, according to another embodiment of the present invention.

In the embodiment of FIG. 11, an operation of the controller 200 in the case of DATA-IN is illustrated.

In step S1101, the controller 200 generates the transmission count information on the data DATA-IN to be transmitted to the semiconductor memory device 100. According to various embodiments, the data DATA-IN to be transmitted to the semiconductor memory device 100 may be raw data received from the host, data obtained by adding the ECC to the raw data, or data completely randomized and finally transmitted from the controller 200.

In step S1103, the controller 200 transmits the command, the address, and the data DATA-IN to the semiconductor memory device 100. According to an embodiment, the command transmitted by the controller 200 may be a program command for the program operation and the address may include the physical block address for performing the program operation. Here, the physical block address may represent one of the plurality of pages of the memory cell array.

In step S1105, the controller 200 may request the semiconductor memory device 100 to transmit the reception count information of the data DATA-IN. The semiconductor memory device 100 generates the reception count information of the data DATA-IN by counting the number of bits of “O” or “1” included in the data DATA-IN received from the controller 200 in the step S1103 and stores the generated reception count information. The semiconductor memory device 100 receives a command requesting the semiconductor memory device 100 to transmit the reception count information of the data DATA-IN from the controller 200 and may transmit the reception count information to the controller 200 in response to the received command.

In step S1107, the controller 200 receives the reception count information of the data DATA-IN from the semiconductor memory device 100.

In step S1109, the controller 200 determines whether the transmission count information of the data DATA-IN generated by the controller 200 coincides with the reception count information of the data DATA-IN received from the semiconductor memory device 100. When the transmission count information generated by the controller 200 coincides with the reception count information generated by the semiconductor memory device 100, it is determined that the transmission errors do not occur. Therefore, when the transmission count information coincides with the reception count information, the process proceeds to step S1111.

In the step S1111, the controller 200 transmits the operation start command to the semiconductor memory device 100.

The semiconductor memory device 100 performs an operation of the command received in the step S1103 in response to the operation start command transmitted by the controller 200.

When the transmission count information generated by the controller 200 does not coincide with the reception count information generated by the semiconductor memory device 100 as a result of the step S1109, it is determined that the transmission errors occur and thus the operation start command is not transmitted to the semiconductor memory device 100. Therefore, the controller 200 may prevent an operation from being performed on the data DATA-IN in which the transmission errors occur. In this case, the process proceeds to the step S1103 and the controller 200 may transmit the command, the address, and the data DATA-IN to the semiconductor memory device 100 again. According to an embodiment, the controller 200 does not transmit the command and the address but transmits only data DATA-IN required to be retransmitted to the semiconductor memory device 100 at step S1103 during the retransmission operation.

According to an embodiment, operations S1105 and S1109 may be omitted during the retransmission operation. Therefore, the controller 200 does not request the semiconductor memory device 100 to transmit the reception count information of the data DATA-IN and the process proceeds to the step S1111 so that the controller 200 may transmit the operation start command to the semiconductor memory device 100.

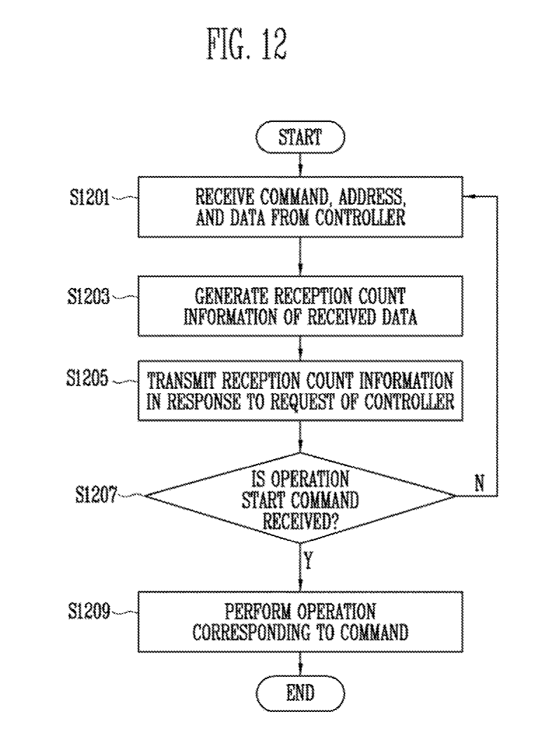

Referring now to FIG. 12 yet another embodiment of an operation of the semiconductor memory device 10 is provided.

In the embodiment of FIG. 10, an operation of the semiconductor memory device 100 in the case of DATA-IN is illustrated.

In step S1201, the semiconductor memory device 100 may receive the command, the address, and the data DATA-IN from the controller 200. According to an embodiment, the command received by the semiconductor memory device 100 may be the program command for the program operation and the address may include the physical block address for performing the program operation. Here, the physical block address may represent one of the plurality of pages of the memory cell array.

In step S1203, the semiconductor memory device 100 generates the reception count information of the received data DATA-IN.

Specifically, the semiconductor memory device 100 generates the reception count information of the data DATA-IN by counting the number of bits of “0” or “1” included in the received data DATA-IN and stores the generated reception count information. The semiconductor memory device 100 does not immediately handle the command received in the step S1201 and holds operation (e.g., the program operation) handling the command.

In step S1205, the semiconductor memory device 100 is requested by the controller 200 to transmit the reception count information of the data DATA-IN and transmits the reception count information to the controller 200 in response to the request. Specifically, when the semiconductor memory device receives the command requesting the semiconductor memory device to transmit the reception count information of the data DATA-IN from the controller 200, the semiconductor memory device 100 may transmit the reception count information generated in the step S1203 to the controller 200 in response to the received command.

In step S1207, the semiconductor memory device 100 may determine whether the operation start command is received from the controller 200. As described above with reference to steps S1107 and S1109 of FIG. 11, the controller 200 receives the reception count information transmitted by the semiconductor memory device 100 in the step S1205 and may determine whether the received reception count information of the data DATA-IN coincides with the transmission count information of the data DATA-IN. When the reception count information coincides with the transmission count information as the result of step S1109, the controller 200 transmits the operation start command to the semiconductor memory device 100 as described above with reference to step S1111 of FIG. 11.

When the semiconductor memory device 100 receives the operation start command from the controller 200, the process proceeds to step S1209.

At step S1209, the semiconductor memory device 100 may perform an operation corresponding to the command received in the step S1201 in response to the operation start command.

As described with reference to steps S1109 and S1103, when the reception count information does not coincide with the transmission count information, the controller 200 does not transmit the operation start command but transmits the command, the address, and the data DATA-IN to the semiconductor memory device 100 again. As described above, the controller 200 does not transmit the command and the address and may transmit only the data DATA-IN required to be retransmitted to the semiconductor memory device 100.

At step S1207, when it is determined that the operation start command is not received, the process proceeds to the step S1201 and the semiconductor memory device 100 receives the command, the address, and the data DATA-IN again from the controller 200.

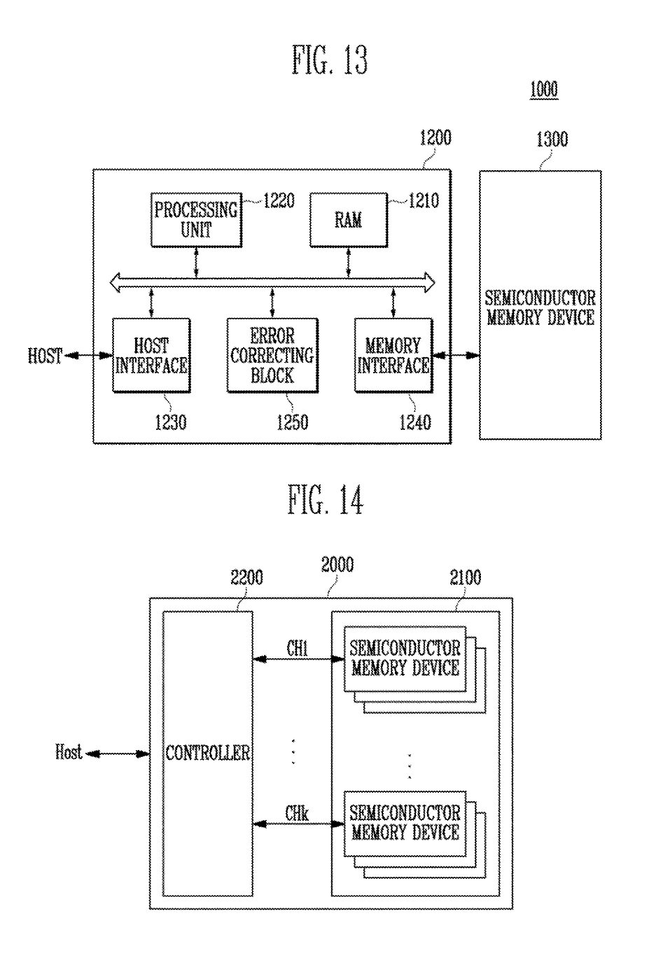

FIG. 13 is a block diagram illustrating a memory system 1000 including the semiconductor memory device of FIG. 3, according to an embodiment of the present invention.

Referring to FIG. 13, the memory system 1000 includes a semiconductor memory device 1300 and a controller 1200.

The semiconductor memory device 1300 may be configured and operate like the semiconductor memory device 100 described with reference to FIG. 3. Hereinafter, description of repeated contents will not be given.

The controller 1200 is connected to a host Host and the semiconductor memory device 1300. In response to a request from the host Host, the controller 1200 accesses the semiconductor memory device 1300. For example, the controller 1200 controls a read operation, a program operation, an erase operation, and a background operation of the semiconductor memory device 1300. The controller 1200 controls interface between the semiconductor memory device 1300 and the host Host. The controller 1200 drives firmware for controlling the semiconductor memory device 1300.

The controller 1200 includes a random access memory (RAM) 1210, a processing unit 1220, a host interface 1230, a memory interface 1240, and an error correcting block 1250.

The RAM 1210 is used as at least one of an operation memory of the processing unit 1220, a cache memory between the semiconductor memory device 1300 and the host Host, and a buffer memory between the semiconductor memory device 1300 and the host Host.

The processing unit 1220 controls an entire operation of the controller 1200.

The processing unit 1220 may randomize data received from the host Host. For example, the processing unit 1220 randomizes the data received from the host Host by using a randomizing seed. The randomized data is provided to the semiconductor memory device 1300 as the data DATA (refer to FIG. 3) to be stored and is programed in the memory cell array 110 (refer to FIG. 3).

The processing unit 1220 may randomize the data received from the semiconductor memory device 1300 during the read operation. For example, the processing unit 1220 may derandomize the data received from the semiconductor memory device 1300 by using a derandomizing seed. The derandomized data is output to the host Host.

According to an embodiment, the processing unit 1220 may perform randomization and derandomization of the data by driving software and/or firmware.

The host interface 1230 may include protocols for exchanging data between the host Host and the controller 1200. According to an exemplary embodiment, the controller 1200 communicates with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA (SATA) protocol, a parallel-ATA (PATA) protocol, a small computer small interface (SCSI) protocol, an enhanced small disk interface (ESDI) protocol, and an integrated drive electronics (IDE) protocol.

The memory interface 1240 interfaces with the semiconductor memory device 1300. For example, the memory interface 1240 may include a NAND interface or a NOR interface.

The error correcting block 1250 detects errors of the data received from the semiconductor memory device 1300 by using an error correcting code (ECC) and corrects the detected errors.

The controller 1200 and the semiconductor memory device 1300 may be integrated into one semiconductor device. According to an exemplary embodiment, the controller 1200 and the semiconductor memory device 1300 are integrated into one semiconductor device and may form a memory card, such as, for example, a personal computer memory card international association (PCMCIA) card, a compact flash (CF) card, a smart media card (SM and SMC), a memory stick, a multimedia card (MMC, RS-MMC, and MMCmicro), an SD card (SD, miniSD, microSD, and SDHC), and a universal flash memory device (UFS).

The controller 1200 and the semiconductor memory device 1300 are integrated into one semiconductor device and may form a semiconductor drive (a solid state drive (SSD)). The semiconductor drive (SSD) includes a storage device formed to store data in a semiconductor memory. When the memory system 1000 is used as the semiconductor drive (SSD), an operation speed of the host Host connected to the memory system 1000 remarkably increases.

According to another example, the memory system 1000 is provided as one of various elements of an electronic device, such as, one of various elements that form a computer, an ultra-mobile PC (UMPC), a work station, a net-book, a personal digital assistant (PDA), a portable computer, a web tablet, a wireless phone, a mobile phone, a smart phone, an e-book, a portable multimedia player (PMP), a portable gamer, a navigator, a black box, a digital camera, a three-dimensional television set, a digital audio recorder, a digital audio player, a digital picture recorder, a digital picture player, a digital video recorder, a digital video player, a device capable of transmitting and receiving information in a wireless environment, one of various electronic devices that form a home network, one of various electronic devices that form a computer network, one of various electronic devices that form a telematics network, an RFID device, or a computing system.

According to an exemplary embodiment, the semiconductor memory device 1300 or the memory system 1000 may be mounted as a package in various forms including, for example, a package on package (PoP), ball grid arrays (BGAs), chip scale packages (CSPs), a plastic leaded chip carrier (PLCC), a plastic dual in line package (PDIP), a die in waffle pack, a die in wafer form, a chip on board (COB), a ceramic dual in line package (CERDIP), a plastic metric quad flat pack (MQFP), a thin quad flat pack (TQFP), a small outline integrated circuit (SOIC), a shrink small outline package (SSOP), a thin small outline package (TSOP), a thin quad flat pack (TQFP), a system in package (SIP), a multichip package (MCP), a wafer-level fabricated package (WFP), and a wafer-level processed stack package (WSP).

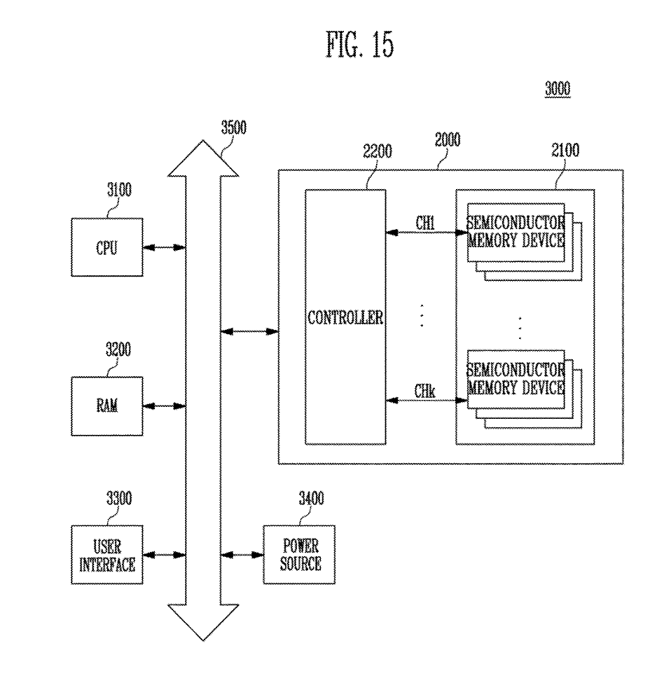

FIG. 14 is a block diagram illustrating an application example 2000 of the memory system 1000 of FIG. 13.

Referring to FIG. 14, the memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 14, it is illustrated that the plurality of groups communicate with the controller 2200 through first to kth channels CH1 to CHk. Each semiconductor memory chip is configured and operates like one of the semiconductor memory device 100 described with reference to FIG. 1.

Each group communicates with the controller 2200 through a common channel. The controller 2200 is configured like the controller 1200 described with reference to FIG. 13 and controls the plurality of semiconductor memory chips of the memory device 2100 through the plurality of channels CH1 to CHk.

In FIG. 14, it is illustrated that the plurality of semiconductor memory chips are connected to one channel. However, the memory system 200 may be modified so that one semiconductor memory chip is connected to one channel.

FIG. 15 is a block diagram illustrating a computing system 3000 including the memory system 2000 illustrated with reference to FIG. 14, according to an embodiment of the present invention.

Referring to the embodiment of FIG. 15, the computing system 3000 includes a central processing unit (CPU) 3100, a RAM 3200, a user interface 3300, a power source 3400, a system bus 3500, and the memory system 2000.

The memory system 2000 is electrically connected to the CPU 3100, the RAM 3200, the user interface 3300, and the power source 3400 through the system bus 3500. Data provided through the user interface 3300 or processed by the CPU 3100 is stored in the memory system 2000.

In FIG. 15, the semiconductor memory device 2100 is illustrated as being connected to the system bus 3500 through the controller 2200. However, the semiconductor memory device 2100 may be directly connected to the system bus 3500 in which case, a function of the controller 2200 may be performed by the CPU 3100 and the RAM 3200.

In FIG. 15, it is illustrated that the memory system 2000 described with reference to FIG. 14 is provided. However, the memory system 2000 may be replaced by the memory system 1000 described with reference to FIG. 14. According to an embodiment, the computing system 3000 may include both the memory systems 1000 and 2000 described with reference to FIGS. 13 and 14.

According to the various embodiments of the present invention, in a case of DATA-OUT, the count information generated by the semiconductor memory device 100 may be used for determining states of the memory cells included in the semiconductor memory device 100 as well as detecting the transmission errors.

Specifically, the controller 200 randomizes the data DATA-IN transmitted to the semiconductor memory device 100 and controls the number of bits of “1” to be similar to the number of bits of “O” in the data DATA-IN. The controller 200 counts the number of bits of “1” and “0” of the data DATA-OUT read from the semiconductor memory device 100, optimizes a read voltage in order to perform a read retry operation, and performs an operation for correcting errors of the data DATA-OUT. That is, since the number of bits of “1” and “0” of the data DATA-OUT has a value dependent on the distribution of threshold voltages of the memory cells due to characteristics of the semiconductor memory device 100, the distribution of the threshold voltages of the memory cells may be inversely traced from the number of bits of “1” and “0” of the data DATA-OUT.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various other changes including in the form and details may be made without departing from the spirit and scope of the present invention as set forth in the following claims.

What is claimed is:

1. A method of operating a controller configured to control a semiconductor memory device, the method comprising:
generating reception count information by counting a number of bits of a predetermined value of data received from the semiconductor memory device;
requesting the semiconductor memory device to transmit transmission count information representing a number of bits of the predetermined value of the data transmitted by the semiconductor memory device; and
determining whether transmission errors are included in the received data based on the reception count information and the transmission count information.

2. The method of claim 1, wherein the determining includes determining that the transmission errors are not included in the received data when the reception count information coincides with the transmission count information.

3. The method of claim 1, further comprising requesting the semiconductor memory device to retransmit the received data when the transmission errors are included in the received data.

4. A controller configured to control a semiconductor memory device, the controller comprising:
a count information generator configured to generate reception count information by counting a number of bits of a predetermined value of data received from the semiconductor memory device; and
a processor configured to request the semiconductor memory device to transmit transmission count information representing a number of bits of the predetermined value of the data transmitted by the semiconductor memory device, and to determine whether transmission errors are included in the received data based on the reception count information and the transmission count information.

5. The controller of claim 4, wherein the count information generator comprises:
a one bit counter configured to count the number of bits of the predetermined value of the received data; and
a register configured to store an output of the one bit counter.

6. The controller of claim 4, wherein the processor determines that the transmission errors are not included in the received data when the reception count information coincides with the transmission count information.

7. The controller of claim 4, wherein the processor requests the semiconductor memory device to retransmit the received data when the transmission errors are included in the received data.

8. The controller of claim 4, the predetermined value is “0” or “1” of the data.

9. A memory system comprising:
a semiconductor memory device configured to transmit data stored in a plurality of memory cells, and to generate transmission count information by counting a number of bits of a predetermined value of the transmitted data; and
a controller configured to generate reception count information by counting a number of bits of the predetermined value of data received from the semiconductor memory device, and to detect transmission errors of the received data based on the transmission count information and the reception count information.

10. The memory system of claim 9, wherein the controller comprising:
a count information generator configured to generate the reception count information by counting the number of bits of a predetermined value of data received from the semiconductor memory device; and
a processor configured to request the semiconductor memory device to transmit transmission count information representing a number of bits of the predetermined value of the data transmitted by the semiconductor memory device, and to determine whether transmission errors are included in the received data based on the reception count information and the transmission count information.

11. The memory system of claim 10, wherein the processor determines that the transmission errors are not included in the received data when the reception count information coincides with the transmission count information.

12. The memory system of claim 10, wherein the processor requests the semiconductor memory device to retransmit the received data when the transmission errors are included in the received data.

13. The memory system of claim 9, wherein the semiconductor memory device comprising:
a count information generator configured to generate transmission count information by counting a number of bits of a predetermined value of data to be transmitted to a controller configured to control the semiconductor memory device; and
a control logic configured to transmit the data to the controller, and to transmit the transmission count information to the controller in response to a request to transmit the transmission count information.

14. The memory system of claim 13, wherein the count information generator comprises:
a one bit counter configured to count the number of bits of the predetermined value of the data to be transmitted; and
a register configured to store an output of the one bit counter.

15. The memory system of claim 13, wherein the control logic retransmits the data to the controller in response to a retransmission command when it is determined that the transmission errors are included in the transmitted data.

16. The memory system of claim 9, wherein the predetermined value is “0” or “1” of the data.
